(19) United States
(12) Patent Application Publication
(10) Pub. No.: US 2025/0280675 A1
(43) Pub. Date: Sep. 4, 2025

(54) Light Emitting Display Apparatus

(71) Applicant: LG Display Co., Ltd., Seoul (KR)

(72) Inventors: MunChae Yoon, Paju-si (KR); KyungYun Kang, Paju-si (KR); EunJi Park, Paju-si (KR)

(21) Appl. No.: 18/946,656

(22) Filed: Nov. 13, 2024

(30) Foreign Application Priority Data
Feb. 29, 2024 (KR) 10-2024-0030282

(51) Int. Cl. H10K 59/131; H10K 59/124

(52) U.S. Cl. CPC H10K 59/131; H10K 59/124

(57) ABSTRACT

A light emitting display apparatus presented herein comprises a substrate, a first metal layer on the substrate, a first insulating layer on the first metal layer, a semiconductor layer on the first insulating layer, a second insulating layer on the semiconductor layer, and a second metal layer on the second insulating layer, wherein at least one thin film transistor comprises the semiconductor layer which is in contact with the first metal layer and is not in contact with the second metal layer.

### CROSS-REFERENCE TO RELATED APPLICATION

This application claims priority of Republic of Korea Patent Application No. 10-2024-0030282 filed on Feb. 29, 2024, which is hereby incorporated by reference in its entirety.

### BACKGROUND

### Field

The present disclosure relates to a light emitting display apparatus.

### Description of Related Art

With the development of information society, the demand for a display apparatus for displaying an image is increasing in various forms. Accordingly, display apparatuses such as a liquid crystal display LCD apparatus, an organic light emitting display OLED apparatus, a micro light emitting diode LED display apparatus, a quantum dot display QD apparatus, and the like are used.

Among these display apparatuses, the organic light emitting display apparatus uses a self-luminous light emitting element without using a separate light source, unlike the liquid crystal display apparatus. Thus, the organic light emitting display apparatus is largely used in a display field owing a thin profile and an excellent image quality. In the organic light emitting display apparatus, a low reflective metal layer is applied to metal layers for connecting main nodes so as to prevent light emitted from an internal pixel or incident light transmitted from the outside from being reflected.

However, since the low reflective metal layer may remain as a residual film in a process of forming metal layers in the main nodes through an insulating layer or forming a large number of contact holes for connecting the metal layer and a semiconductor layer, which might a problem of a contact failure. Accordingly, there is an increasing demand for the efficient space arrangement and connection structure between components capable of preventing the contact failure by the low reflective metal layer.

### SUMMARY

The present disclosure has been made in view of the above problems, and it is an object of the present disclosure to provide a light emitting display apparatus in which a contact hole is formed before an active layer, which enables to connect a first metal layer to the active layer, and to configure a thin film transistor without a contact hole for connecting a second metal layer so that it is possible to reduce the number of contact holes, thereby preventing a contact defect caused by a low reflective metal layer and improving an efficient space arrangement and connection structure of the thin film transistor.

The objects of the present disclosure are not limited to the aforesaid, but other objects not described herein will be clearly understood by those skilled in the art from descriptions below.

In accordance with one or more embodiments of the present disclosure, the above and other objects may be accomplished by the provision of a light emitting display apparatus comprising a substrate, a first metal layer on the substrate, a first insulating layer on the first metal layer, a semiconductor layer on the first insulating layer, a second insulating layer on the semiconductor layer, and a second metal layer on the second insulating layer, wherein at least one thin film transistor comprises the semiconductor layer which is in contact with the first metal layer and is not in contact with the second metal layer.

In accordance with one or more embodiments of the present disclosure, the above and other objects may be accomplished by the provision of a light emitting display apparatus comprising a substrate including a plurality of subpixels, a first metal layer on the substrate, a first insulating layer on the first metal layer, a semiconductor layer on the first insulating layer, a planarization layer covering the first insulating layer and the semiconductor layer, and a light emitting element on the planarization layer, wherein the semiconductor layer is connected to the first metal layer through at least one contact hole passing through the first insulating layer, and wherein the plurality of subpixels may include a driving transistor, and a pixel electrode of the light emitting element is connected to the semiconductor layer of the driving transistor through a contact hole passing through the planarization layer.

According to one or more embodiments of the present disclosure, it is possible to provide the light emitting display apparatus in which the contact hole is formed before the active layer, which enables to connect the first metal layer to the active layer, and to configure the thin film transistor without the contact hole for connecting the second metal layer so that it is possible to reduce the number of contact holes, thereby preventing the contact defect caused by the low reflective metal layer and improving the efficient space arrangement and connection structure of the thin film transistor.

The light emitting display apparatus according to one or more embodiments of the present disclosure may reduce the number of contact holes so that it is possible to prevent the contact defect caused by the low reflective metal layer, thereby improving the reliability of manufacturing process and reducing the manufacturing process for producing the light emitting display apparatus. Accordingly, it is possible to implement Environment/Social/Governance ESG by reducing the generation of greenhouse gas that may occur due to the manufacturing process.

The effects of the present disclosure are not limited to the aforesaid, but other effects not described herein will be clearly understood by those skilled in the art from descriptions below.

The details of the present disclosure described in technical problem, technical solution, and advantageous effects do not specify essential features of claims, and thus, the scope of claims is not limited by the details described in detailed description of the invention.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 illustrates a light emitting display apparatus according to one or more embodiments of the present disclosure.

FIG. 2 is a block diagram illustrating a light emitting display apparatus according to one or more embodiments of the present disclosure.

FIG. 3 is a circuit diagram illustrating a subpixel of a light emitting display apparatus according to one or more embodiments of the present disclosure.

FIG. 4 is a plan view illustrating a subpixel of a light emitting display apparatus according to one or more embodiments of the present disclosure.

FIG. 5 is a cross-sectional view along line I-I′ of FIG. 4 according to one or more embodiments of the present disclosure.

FIG. 6 is a circuit diagram of a subpixel shown in FIG. 4 according to one or more embodiments of the present disclosure.

FIG. 7 illustrates a node voltage of a driving transistor in the subpixel shown in FIG. 4 according to one or more embodiments of the present disclosure.

FIGS. 8 to 11 illustrate a method of forming the subpixel shown in FIG. 4 according to one or more embodiments of the present disclosure.

FIG. 12 is a plan view illustrating a subpixel of a light emitting display apparatus according to one or more embodiments of the present disclosure.

FIG. 13 is a cross-sectional view along line II-II′ of FIG. 12 according to one or more embodiments of the present disclosure.

FIG. 14 is a circuit diagram of a subpixel shown in FIG. 12 according to one or more embodiments of the present disclosure.

FIG. 15 illustrates a node voltage of a driving transistor in the subpixel shown in FIG. 12 according to one or more embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe embodiments, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more embodiments, the components of each apparatus according to various embodiments of the present disclosure are operatively coupled and configured.

In the following description, various embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

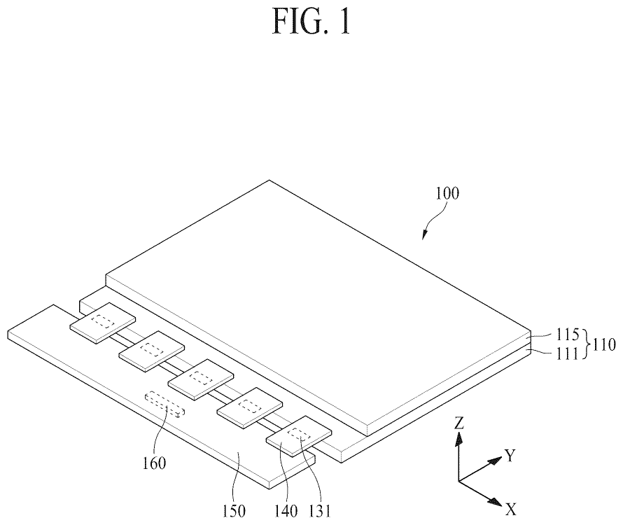

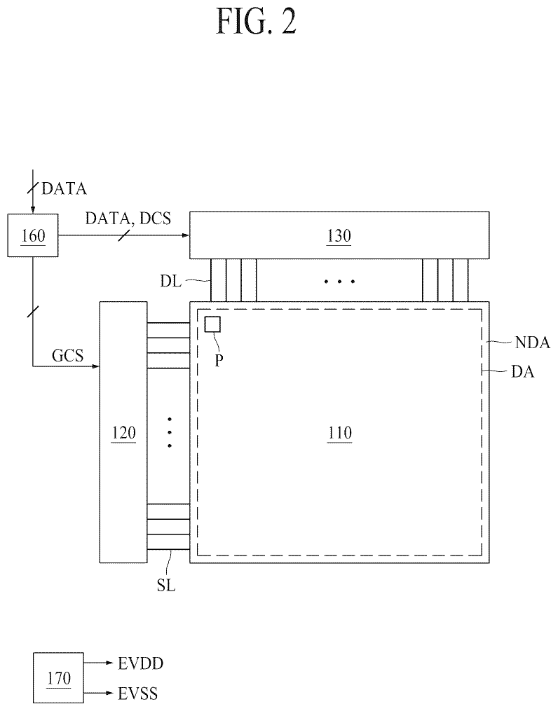

FIG. 1 illustrates a light emitting display apparatus according to one or more embodiments of the present disclosure. FIG. 2 is a block diagram illustrating a light emitting display apparatus according to one or more embodiment of the present disclosure.

A light emitting display apparatus 100 according to one or more embodiments of the present disclosure is implemented as an organic light emitting display apparatus, but may also be implemented as a liquid crystal display apparatus, a quantum dot lighting emitting diode display apparatus, or an electrophoretic display apparatus.

Referring to FIGS. 1 and 2, the light emitting display apparatus 100 according to an embodiment of the present disclosure may include a display panel 110, a scan driver 120 embedded in the display panel 110, a data driver 130 connected to the display panel 110, a timing controller 160 controlling the scan driver 120 and the data driver 130, and a power circuit 170.

The display panel 110 may include a substrate 111 and an opposite substrate 115. The opposing substrate 115 may be an encapsulation substrate. The substrate 111 may include a plastic film or a glass substrate, but embodiments of the present disclosure are not limited thereto. For example, the substrate 111 may be formed of a semiconductor material such as a silicon wafer. The opposite substrate 115 may be a plastic film, a glass substrate, or an encapsulation film (or protection film).

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus 100. For example, the subpixels SP may be formed in a top emission type, a bottom emission type, or a dual emission type according to the structure. The subpixels SP indicate a unit capable of forming a color filter of a specific type or capable of emitting a color of itself without forming a color filter. For example, the subpixels SP may include a red subpixel, a green subpixel, and a blue subpixel. Alternatively, the subpixels SP may include a red subpixel, a blue subpixel, a white subpixel, and a green subpixel. The subpixels SP may have one or more other light-emitting areas according to light-emitting characteristics. For example, the plurality of subpixels SP may be arranged in a quad type or a stripe type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL connected to the subpixels SP. The data lines DL may be arranged to cross the scan lines SL. Each of the plurality of data lines DL may be configured to extend in a first direction. Each of the plurality of gate lines GL may be configured to extend in a second direction different from the first direction. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The data driver 130 may include a plurality of data drive ICs 131 as shown in FIG. 1. Each of the plurality of data drive ICs 131 may be mounted on the flexible film 140 by chip on film COF, chip on plastic COP, Flexible Printed Circuit FPC, or Flexible Flat Cable FFC. The flexible film 140 is attached on pads provided in the non-display area NDA of the display panel 110 by using an anisotropic conducting film, whereby the plurality of data drive ICs 131 may be connected to the pads.

The circuit board 150 may be attached to the flexible films 140. A plurality of circuits implemented as driving chips may be mounted on the circuit board 150. For example, the timing controller 160 may be mounted on the circuit board 150. The circuit board 150 may be a printed circuit board or a flexible printed circuit board.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period required for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 to control the scan driver 120 and output the digital video data DATA and data control signal DCS to the data driver 130 to control the data driver 130.

The power circuit 170 may generate and supply a plurality of driving voltages required for an operation of all circuit configurations of the display apparatus 100 by using an input voltage. The power circuit 170 may generate a first power source voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages required for operations of the gate driver 120, the data driver 130, and the timing controller 160.

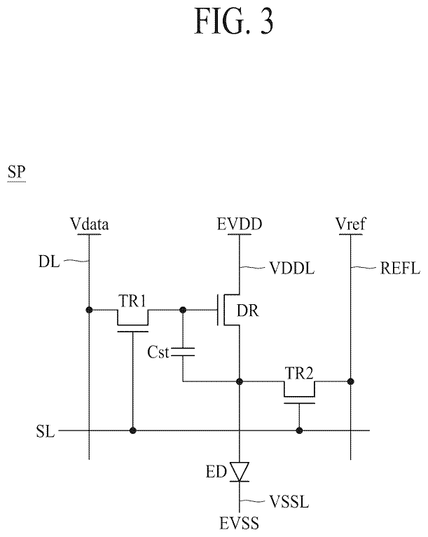

FIG. 3 is a circuit diagram illustrating a subpixel of a light emitting display apparatus according to one or more embodiments of the present disclosure.

Referring to FIG. 3, each of pixels includes a plurality of subpixels SP constituting a unit pixel. In each of the plurality of subpixels SP, there are a pixel circuit having 3T (Transistor) 1C (Capacitor) including a driving transistor DR, a first switching transistor TR1, a second switching transistor TR2 and a storage capacitor Cst, and a light emitting element ED, but not limited thereto. Each subpixel SP may further include a compensation circuit. In this case, the subpixel SP may have various structures such as 4T2C, 5T2C, 6T1C, 6T2C, 7T1C, and 7T2C.

At least one thin film transistor DR, TR1, and TR2 of each subpixel SP may be implemented as an oxide thin film transistor TFT including an oxide semiconductor, a low temperature poly silicon thin film transistor LTPS TFT including LTPS, and the like. In addition, each of the thin film transistors may be a P-type or an N-type, or a P-type and an N-type may be interchangeably used.

The at least one thin film transistor DR, TR1, and TR2 is a three-electrode element including a gate, a source, and a drain. The source is an electrode for supplying a carrier to the transistor. In the at least one thin film transistor DR, TR1, and TR2, the carrier starts to flow from the source. In the at least one thin film transistor DR, TR1, and TR2, the carrier flows from the source to the drain. In the case of N-type transistor, since the carrier is an electron, a source voltage is lower than a drain voltage so that the electron flows from the source to the drain. In the N-type transistor, a current direction flows from the drain to the source. In the case of P-type transistor PMOS, since the carrier is a hole, a source voltage is higher than a drain voltage so that the hole flows from the source to the drain. In the P-type transistor, since the hole flows from the source to the drain, a current flows from the source to the drain. The source and drain of the at least one thin film transistor DR, TR1, and TR2 are not fixed, and the source and the drain may be changed according to an applied voltage, but embodiments of the present disclosure are not limited thereto. Any one of the source and the drain may be represented as a first electrode, and the other may be represented as a second electrode.

A gate signal may swing between a gate-on voltage and a gate-off voltage. The gate-on voltage may be set to a voltage which is higher than a threshold voltage of the at least one thin film transistor DR, TR1, and TR2, and the gate-off voltage may be set to a voltage which is lower than the threshold voltage of the at least one thin film transistor DR, TR1, and TR2. The at least one thin film transistor DR, TR1, and TR2 may be turned-on in response to the gate-on voltage, whereas the at least one thin film transistor DR, TR1, and TR2 may be turned-off in response to the gate-off voltage. In the case of N-type transistor, the gate-on voltage may be a gate high voltage VGH, and the gate-off voltage may be a gate low voltage VGL. In the case of P-type transistor, the gate-on voltage may be a gate low voltage VGL, and the gate-off voltage may be a gate high voltage VGH.

The first switching transistor TR1 may be turned-on in response to a scan signal Scan applied through a scan line SL (or gate line). When the first switching transistor TR1 is turned-on, a data voltage Vdata applied through a data line DL may be transferred to one end of the storage capacitor Cst.

The second switching transistor TR2 may serve to supply a reference voltage Vref supplied from a reference line REFL to the driving transistor DR. For example, a gate electrode of the second switching transistor TR2 may be connected to the scan line SL (or gate line), and a first electrode of the second switching transistor TR2 may be connected to the reference line REFL. In addition, a second electrode of the second switching transistor TR2 may connected to a first electrode of the driving transistor DR and the other end of the storage capacitor Cst.

The second switching transistor TR2 may be turned-on in response to the scan signal Scan applied through the scan line SL (or gate line). When the second switching transistor TR2 is turned-on, the reference voltage Vref applied through the reference line REFL may be transferred to the other end of the storage capacitor Cst. In addition, the reference voltage Vref may also be applied to a source electrode of the driving transistor DR.

The storage capacitor Cst maintains the data voltage Vdata supplied to the driving transistor DR for one frame. For example, the storage capacitor Cst may have a first electrode connected to a gate electrode of the driving transistor DR, and a second electrode connected to the source electrode of the driving transistor DR. The storage capacitor Cst may store a voltage corresponding to the data voltage Vdata transferred through the first switching transistor TR1, and may turn on the driving transistor DR with the stored voltage.

The driving transistor DR generates a data current from a first power source EVDD supplied from a pixel power line VDDL (or first power line) and supplies the data current to an anode electrode of the light emitting element ED. For example, the gate electrode of the driving transistor DR is connected to one end of the storage capacitor Cst, and the first electrode of the driving transistor DR is connected to the pixel power line VDDL. Also, a second electrode of the driving transistor DR is connected to the anode electrode of the light emitting element ED.

The light emitting element ED may include the anode electrode connected to the driving transistor DR, a cathode electrode supplied with a second power source EVSS from a common power line VSSL (or second power line), and an emission layer between the anode electrode and the cathode electrode. The anode electrode is an independent electrode for each light emitting element, but the cathode electrode may be a common electrode shared by the entire light emitting elements. When the driving current is supplied from the driving transistor DR to the light emitting element ED, electrons from the cathode electrode are injected into the emission layer, and holes from the anode electrode are injected into the emission layer, whereby fluorescent or phosphorescent materials emit through recombination of electrons and holes in the emission layer, thereby generating light of brightness proportional to a current value of the driving current.

The anode electrode of the light emitting element ED is connected to the second electrode of the driving transistor DR, and the cathode electrode of the light emitting element ED is connected to the common power line VSSL. The light emitting element ED may emit light in response to the driving current generated by the driving transistor.

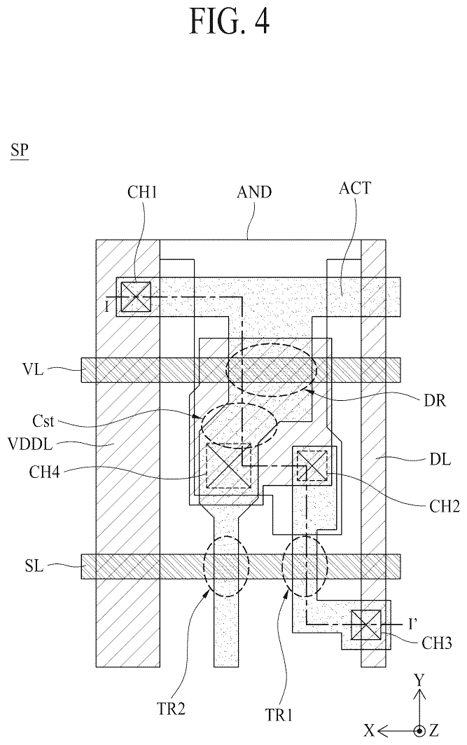

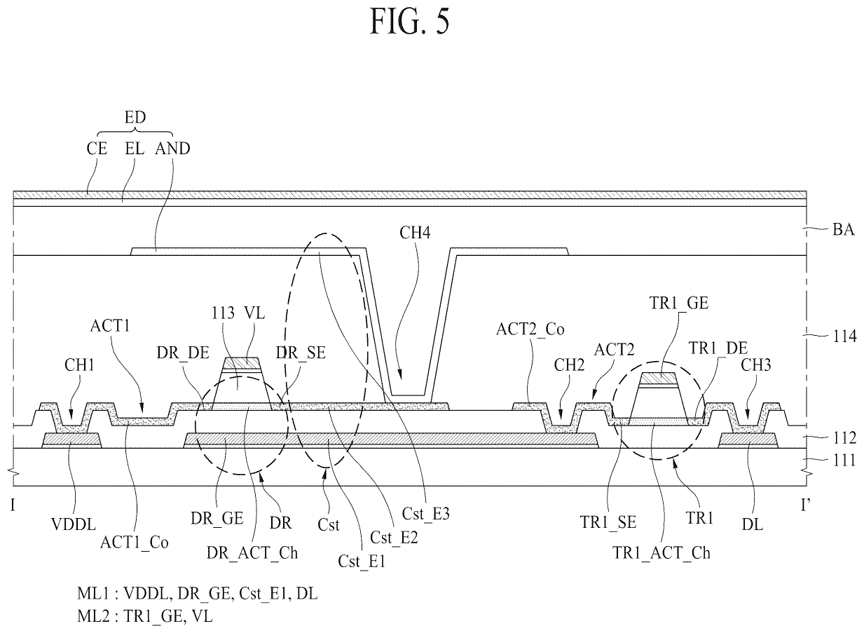

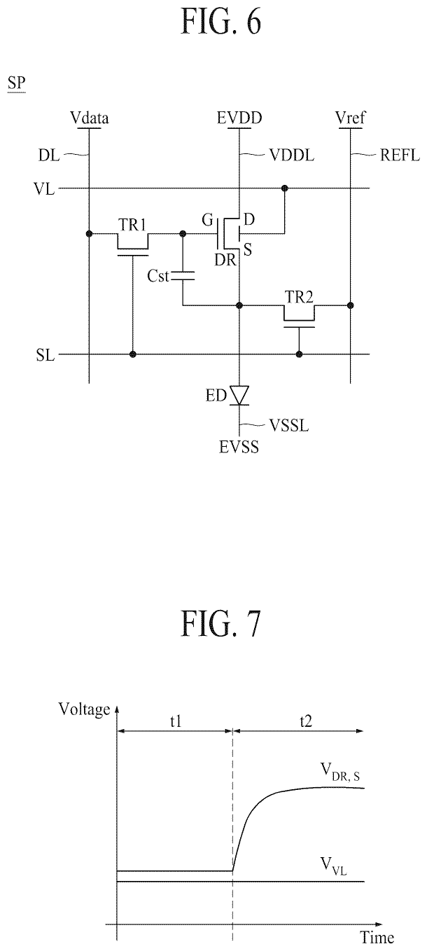

FIG. 4 is a plan view illustrating a subpixel of a light emitting display apparatus according to one or more embodiments of the present disclosure. FIG. 5 is a cross-sectional view along line I-I′ of FIG. 4 according to one or more embodiments of the present disclosure. FIG. 6 is a circuit diagram of the subpixel shown in FIG. 4 according to one or more embodiments of the present disclosure. FIG. 7 illustrates a node voltage of a driving transistor in the subpixel shown in FIG. 4 according to one or more embodiments of the present disclosure.

Referring to FIGS. 4 to 7, the subpixel SP according to an embodiment of the present disclosure may include a pixel circuit including at least one thin film transistor DR, TR1, and TR2, and a storage capacitor Cst. For example, the at least one thin film transistor DR, TR1, and TR2 may include a driving transistor DR, a first switching transistor TR1, and a second switching transistor TR2. The subpixel SP may include a light emitting element ED for receiving a driving current through the pixel circuit and emitting light. For example, the light emitting element ED may include a first electrode AND (or anode electrode, pixel electrode), an emission layer EL (or organic light emitting layer), and a second electrode CE (or cathode electrode, common electrode). At least one power line and at least one signal line may be disposed in the subpixel SP. For example, the at least one power line may include a first power line VDDL (or pixel power line) and a second power line VSSL (or common power line) extending in a first direction (or Y-axis direction). The at least one signal line may include a data line DL and a reference line REFL extending in the first direction (or Y-axis direction), and a scan line SL and an auxiliary signal line VL extending in a second direction (or X-axis direction).

Referring to FIG. 5, in a display panel 110 according to an embodiment of the present disclosure, a first metal layer ML1 is disposed on a substrate 111, a first insulating layer 112 is disposed on the first metal layer ML1, an active layer ACT (or semiconductor layer) is disposed on the first insulating layer 112, a second insulating layer 113 is disposed on the active layer ACT, and a second metal layer ML2 may be disposed on the second insulating layer 113. The at least one thin film transistor DR, TR1, and TR2 may be formed by using the first metal layer ML1, the active layer ACT, and the second metal layer ML2. For example, the active layer ACT may be in contact with the first metal layer ML1 and may be in non-contact with the second metal layer ML2, to thereby form the at least one thin film transistor DR, TR1, and TR2. For example, the second metal layer ML2 may be in non-contact with the active layer ACT and the first metal layer ML1.

The first metal layer ML1 may be disposed on the substrate 111. The first metal layer ML1 may be formed in a single-layered or multi-layered structure of any one or more of molybdenum Mo, aluminum Al, chromium Cr, tungsten W, gold Au, titanium Ti, nickel Ni, neodymium Nd, and copper Cu, or an alloy thereof. The first metal layer ML1 may include a low reflective material layer for a low reflection of external light. For example, the low reflective material layer may be disposed on a lower portion of the first metal layer ML1, and the low reflective material layer may include a metal oxide or an alloy oxide. For example, the low reflective material layer may include copper oxide CuOx, nickel oxide NiOx, molybdenum oxide MoOx, or tungsten oxide WOx, but embodiments of the present disclosure are not limited thereto. For example, the first metal layer ML1 may have a double layer structure including copper Cu and metal oxide.

The first metal layer ML1 may include a first power line VDDL (or pixel power line), a second power line VSSL (or common power line), a data line DL, a reference line REFL, a gate electrode DR_GE of the driving transistor DR, and a first electrode Cst_E1 of the storage capacitor Cst. In FIG. 5, the second power line VSSL and the reference line REFL are omitted.

The first power line VDDL, the second power line VSSL, the data line DL, and the reference line REFL constituting the first metal layer ML1 may extend in a first direction (or Y-axis direction) on the substrate 111. The gate electrode DR_GE of the driving transistor DR constituting the first metal layer ML1 and the first electrode Cst_E1 of the storage capacitor Cst may be configured as an integrated island pattern.

The first insulating layer 112 may be disposed on the substrate 111 and may be configured to cover the first metal layer ML1. The first insulating layer 112 prevents the diffusion of impurity ions or penetration of moisture or external air and insulates the first metal layer ML1 and the active layer ACT from each other. The first insulating layer 112 may be configured in a single-layered structure or multi-layered structure including an inorganic insulating material such as silicon oxide SiO_{X}, silicon nitride SiN_{X}, aluminum oxide Al₂O₃, and the like.

The first insulating layer 112 may include at least one contact hole CH1, CH2, and CH3 exposing at least a portion of the first metal layer ML1. For example, the at least one contact hole CH1, CH2, and CH3 may include a first contact hole CH1, a second contact hole CH2, and a third contact hole CH3. The first contact hole CH1 may be configured to penetrate the first insulating layer 112 to expose at least a portion of the first metal layer ML1 constituting the first power line VDDL. The second contact hole CH2 may be configured to penetrate the first insulating layer 112 to expose at least a portion of the first metal layer ML1 constituting the gate electrode DR_GE of the driving transistor DR. The third contact hole CH3 may be configured to penetrate the first insulating layer 112 to expose at least a portion of the first metal layer ML1 constituting the data line DL.

An active layer ACT (or semiconductor layer) may be disposed on the first insulating layer 112. The active layer ACT may be formed of an oxide semiconductor material or a silicon-based semiconductor material. For example, the active layer ACT may be formed of an oxide semiconductor such as indium gallium zinc oxide IGZO, indium gallium oxide IGO, and indium tin zinc oxide ITZO. For example, the active layer ACT composed of oxide semiconductor may have different conductivity characteristics depending on the content of oxygen. If the content of oxygen decreases, conductivity of the oxide semiconductor may be increased and may be conductive.

The active layer ACT may include a first semiconductor region and a second semiconductor region. The first semiconductor region of the active layer ACT is a region which is overlapped with the second metal layer ML2 and configured not to be conductive. The first semiconductor region may be composed of a semiconductor channel (or channel region) DR_ACT_Ch which is overlapped with the auxiliary signal line VL (or second gate line) of the second metal layer ML2 and a semiconductor channel (or channel region) TR1_ACT_Ch which is overlapped with the gate electrode TR1_GE of the first switching transistor TR1 of the second metal layer ML2 of the at least one thin film transistor DR, TR1, and TR2. The second semiconductor region of the active layer ACT may be formed of a conductive region ACT1_Co and ACT2_Co which becomes conductive, and the second semiconductor region may be composed of a source electrode DR_SE and TR1_SE and a drain electrode DR_DE and TR1_DE of the at least one thin film transistor DR, TR1, and TR2, and the second electrode Cst_E2 of the storage capacitor Cst. The conductive region ACT1_Co and ACT2_Co of the active layer ACT is not covered by the second insulating layer 113 and the second metal layer ML2, and an upper portion of the conductive region ACT1_Co and ACT2_Co is exposed from the second insulating layer 113 and the second metal layer ML2 in a conductive process of the active layer ACT.

The active layer ACT may include a first active layer ACT1 and a second active layer ACT2 spaced apart from each other on the first insulating layer 112.

The first active layer ACT1 may include the semiconductor channel DR_ACT_Ch, the source electrode DR_SE, and the drain electrode DR_DE of the driving transistor DR. Also, the first active layer ACT1 may include the second electrode Cst_E2 of the storage capacitor Cst, and a semiconductor channel and source and drain electrodes of the second switching transistor TR2. In FIG. 5, the semiconductor channel, the source electrode, and the drain electrode of the second switching transistor TR2 are omitted. The conductive region ACT1_Co of the first active layer ACT1 may be in contact with the first metal layer ML1 constituting the first power line VDDL through the first contact hole CH1 penetrating the first insulating layer 112.

The second active layer ACT2 may include the semiconductor channel TR1_ACT_Ch, the source electrode TR1_SE, and the drain electrode TR1_DE of the first switching transistor TR1. The conductive region ACT2_Co of the second active layer ACT2 may be in contact with the first metal layer ML1 constituting the gate electrode DR_GE of the driving transistor DR and the second electrode Cst_E2 of the storage capacitor Cst through the second contact hole CH2 penetrating the first insulating layer 112. In addition, the conductive region ACT2_Co of the second active layer ACT2 may be in contact with the first metal layer ML1 constituting the data line DL through the third contact hole CH3 penetrating the first insulating layer 112.

The second insulating layer 113 may be disposed on the first insulating layer 112 so as to cover at least a portion of the active layer ACT. For example, the second insulating layer 113 may be configured to cover the semiconductor channel DR_ACT_Ch of the first active layer ACT1 and the semiconductor channel TR1_ACT_Ch of the second active layer ACT2. The second insulating layer 113 may be disposed between the active layer ACT and the second metal layer ML2. For example, the second insulating layer 113 may be disposed between the semiconductor channel DR_ACT_Ch of the first active layer ACT1 and the auxiliary signal line VL of the second metal layer ML2. Also, the second insulating layer 113 may be disposed between the semiconductor channel TR1_ACT_Ch of the second active layer ACT2 and the gate electrode TR1_GE of the first switching transistor TR1 of the second metal layer ML2. For example, the second insulating layer 113 may be patterned to remain under the patterns of the second metal layer ML2 in a process of patterning the second metal layer ML2. The second insulating layer 113 prevents diffusion of impurity ions and insulates the active layer ACT and the second metal layer ML2 from each other. The second insulating layer 113 may be configured in a single-layered structure or multi-layered structure including an inorganic insulating material such as silicon oxide SiO_{X}, silicon nitride SiN_{X}, aluminum oxide Al₂O₃, and the like.

The second metal layer ML2 may be disposed on the second insulating layer 113. For example, the auxiliary signal line VL of the second metal layer ML2 may be disposed on the second insulating layer 113, and the gate electrode TR1_GE of the first switching transistor TR1 of the second metal layer ML2 may be disposed on the second insulating layer 113. For example, the second metal layer ML2 may be disposed on the second insulating layer 113 and may be patterned together with the second insulating layer 113. The second metal layer ML2 may be disposed to overlap at least a portion of the active layer ACT. The second metal layer ML2 may mask the active layer ACT in a conductive process of the active layer ACT. Accordingly, the active layer ACT may not become conductive at a portion overlapping the second metal layer ML2. The second metal layer ML2 may be formed in a single-layered or multi-layered structure of any one or more of molybdenum Mo, aluminum Al, chromium Cr, tungsten W, gold Au, titanium Ti, nickel Ni, neodymium Nd, and copper Cu, or an alloy thereof. The second metal layer ML2 may include a low reflective material layer for a low reflection of external light. For example, the low reflective material layer may be disposed on a lower portion of the second metal layer ML2, and the low reflective material layer may include a metal oxide or an alloy oxide. For example, the low reflective material layer may include copper oxide CuOx, nickel oxide NiOx, molybdenum oxide MoOx, or tungsten oxide WOx, but embodiments of the present disclosure are not limited thereto. For example, the second metal layer ML2 may have a double layer structure including copper Cu and metal oxide.

The second metal layer ML2 may include the scan line (or first gate line), the auxiliary signal line VL (or second gate line), the gate electrode TR1_GE of the first switching transistor TR1, and the gate electrode of the second switching transistor TR2. In FIG. 5, the gate electrode of the second switching transistor TR2 is omitted.

The second metal layer ML2 is not in contact with the active layer ACT and the first metal layer ML1, whereby the second metal layer ML2 may serve as a mask pattern of conductive process of the active layer ACT of the at least one thin film transistor DR, TR1, and TR2, and the second metal layer ML2 may be composed of the gate electrode TR1_GE of the first switching transistor TR1 and the gate electrode (not shown) of the second switching transistor TR2.

The auxiliary signal line VL and the scan line SL composed of the second metal layer ML2 may extend in the second direction (or X-axis direction). The scan line SL and the auxiliary signal line VL are parallel to each other in the second direction (or X-axis direction) and are spaced apart from each other in the first direction (or Y-axis direction).

The scan line SL is applied with the scan signal Scan for controlling the first and second switching transistors TR1 and TR2, and may be composed of the gate electrode TR1_GE of each of the first and second switching transistors TR1 and TR2. For example, the scan signal Scan may be applied to the gate electrode TR1_GE of the first switching transistors TR1 and the gate electrode of the second switching transistor TR2 in order to control the first and second switching transistors TR1 and TR2.

The auxiliary signal line VL may be configured to be applied with a voltage different from a first power source voltage EVDD (or driving voltage) applied through the first power line VDDL or to be electrically floated. For example, an auxiliary voltage having a voltage level lower than that of the first power source voltage EVDD may be applied to the auxiliary signal line VL.

A planarization layer 114 may be disposed on the second metal layer ML2. The planarization layer 114 may be an organic insulating layer configured to cover the second metal layer ML2, and to planarize the step difference caused by the at least one thin film transistor DR, TR1, and TR2 and the storage capacitor Cst. For example, the planarization layer 114 may be formed of an organic material such as acryl resin, epoxy resin, phenolic resin, polyamide resin, and polyimide resin. According to one or more embodiments of the present disclosure, a passivation layer may be disposed between the planarization layer 114 and the second metal layer ML2. The passivation layer may be an inorganic insulating layer for protecting a lower structure. According to one or more embodiments of the present disclosure, the passivation layer may be omitted. In addition, a plurality of color filters may be disposed in a light emitting area of each subpixel SP on the passivation layer. For example, when the passivation layer is omitted, the plurality of color filters may be disposed on the first insulating layer 112, but embodiments of the present disclosure are not limited thereto.

The planarization layer 114 may include a fourth contact hole CH4 for exposing at least a portion of the active layer ACT. The fourth contact hole CH4 may be configured to pass through the planarization layer 114 to expose at least a portion of the conductive region ACT1_Co of the first active layer ACT1.

A first electrode AND (or anode electrode), an emission layer EL (or organic light emitting layer), and a second electrode CE (or cathode electrode) of the light emitting element ED and a bank layer BA may be arranged on the planarization layer 114. For example, the bank layer BA may be made of an organic material such as acryl resin, epoxy resin, phenolic resin, polyamide resin, and polyimide resin.

The first electrode AND of the light emitting element ED may be in contact with the conductive region ACT_Co of the first active layer ACT1 through the fourth contact hole CH4 passing through the planarization layer 114. For example, the first electrode AND disposed in the pixel circuit may be in contact with the conductive region ACT1_Co constituting the source electrode DR_SE of the driving transistor DR and the second electrode Cst_E2 of the storage capacitor Cst through the fourth contact hole CH4. Also, the first electrode AND disposed in the pixel circuit may be configured as a third electrode Cst_E3 of the storage capacitor Cst.

Referring to FIGS. 6 and 7, a display panel 110 according to one or more embodiments of the present disclosure may include the auxiliary signal line VL of the second metal layer ML2 as a backgate of the driving transistor DR. For example, the auxiliary signal line VL may be applied with an auxiliary voltage V_{VL} having a voltage level lower than that of a source voltage V_{DR, S} of the driving transistor DR from the outside. The auxiliary voltage V_{VL} may be a constant fixed voltage during a first period t1 and a second period t2 in which the subpixel SP is operated. For example, the first period t1 may be an initialization period and a data program period before the subpixel SP emits light, and the second period t2 may be a light emitting period in which the subpixel SP emits light. For example, the auxiliary voltage V_{VL} may be applied to the backgate of the driving transistor DR to compensate for a threshold voltage of the driving transistor DR.

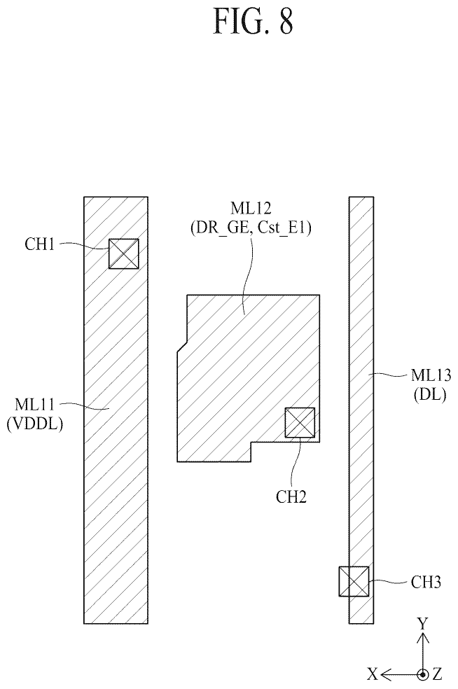

FIGS. 8 to 11 illustrate a method of forming the subpixel shown in FIG. 4 according to one or more embodiments of the present disclosure.

Referring to FIG. 8, the first metal layer ML1 may be formed on the substrate. The first metal layer ML1 may include a (1-1)th metal pattern ML11 constituting the first power line VDDL (or pixel power line), a (1-2)th metal pattern ML12 constituting the gate electrode DR_GE of the driving transistor DR and the first electrode Cst_E1 of the storage capacitor Cst, and a (1-3)th metal pattern ML13 constituting the data line DL. For example, the (1-1)th metal pattern ML11 and the (1-3)th metal pattern ML13 may be formed to extend in the first direction (or Y-axis direction). The (1-1)th metal pattern ML11 and the (1-3)th metal pattern ML13 may be spaced apart from each other in the second direction (or X-axis direction). The (1-2)th metal pattern ML12 may be disposed between the (1-1)th metal pattern ML11 and the (1-3)th metal pattern ML13. For example, the (1-2)th metal pattern ML12 may be formed as an island pattern between the (1-1)th metal pattern ML11 and the (1-3)th metal pattern ML13.

The first insulating layer may be formed on the substrate to cover the first metal layer ML1. In the first insulating layer, the first contact hole CH1 exposing at least a portion of the (1-1)th metal pattern ML11 may be formed therein, the second contact hole CH2 exposing at least a portion of the (1-2)th metal pattern ML12 may be formed therein, and the third contact hole CH3 exposing at least a portion of the (1-3)th metal pattern ML13 may be formed therein.

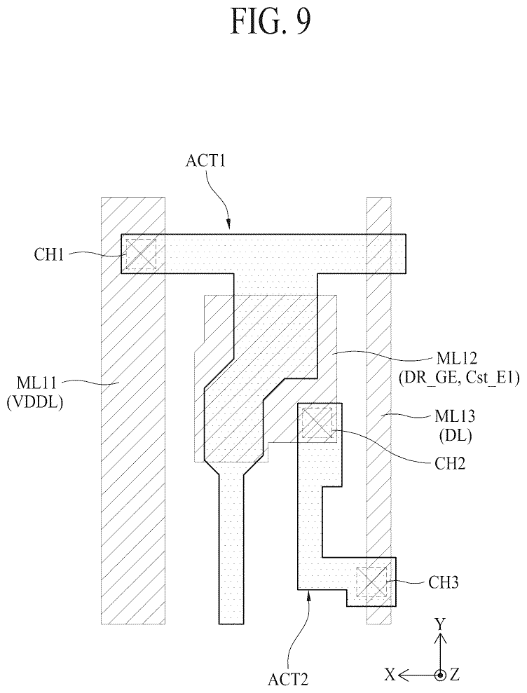

Referring to FIG. 9, the active layer ACT may be formed on the first insulating layer. The active layer ACT may include the first active layer ACT1 and the second active layer ACT2.

The first active layer ACT1 may be formed to overlap at least a portion of the (1-1)th metal pattern ML11, the (1-2)th metal pattern ML12, and the (1-3)th metal pattern ML13. The first active layer ACT1 may be in contact with the (1-1)th metal pattern ML11 through the first contact hole CH1. Also, the first active layer ACT1 may be in contact with at least a portion of the (1-2)th metal pattern ML12, and the (1-3)th metal pattern ML13. The first active layer ACT1 may be composed of the semiconductor channel of the driving transistor DR and the semiconductor channel of the second switching transistor TR2. Also, the first active layer ACT1 becomes conductive so that the first active layer ACT1 may be composed of the source and drain electrodes of the driving transistor DR, the source and drain electrodes of the second switching transistor TR2, and the second electrode of the storage capacitor Cst.

The second active layer ACT2 may be formed to overlap at least a portion of the (1-2)th metal pattern ML12 and the (1-3)th metal pattern ML13. The second active layer ACT2 may be in contact with the (1-2)th metal pattern ML12 through the second contact hole CH2, and may be in contact with the (1-3)th metal pattern ML13 through the third contact hole CH3. The second active layer ACT2 may be configured as the semiconductor region of the first switching transistor TR1. Also, the second active layer ACT2 becomes conductive so that the second active layer ACT2 may be composed of the source and drain electrodes of the first switching transistor TR1.

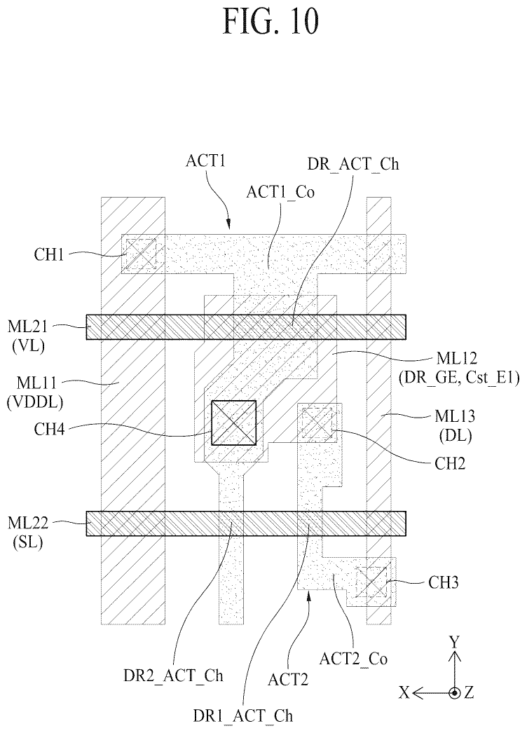

Referring to FIG. 10, the second insulating layer and the second metal layer ML2 may be formed on the active layer ACT. For example, the second insulating layer may be formed on the active layer ACT, and the second metal layer may be disposed on the second insulating layer. That is, the second metal layer may not contact the active layer with the second insulating layer interposed therebetween. The second metal layer ML2 may include a (2-1)th metal pattern ML21 constituting the auxiliary signal line VL (or second gate line), and a (2-2)th metal pattern ML22 constituting the scan line SL (or first gate line). For example, the (2-1)th metal pattern ML21 and the (2-2)th metal pattern ML22 may be formed to extend in the second direction (or X-axis direction). The (2-1)th metal pattern ML21 and the (2-2)th metal pattern ML22 may be spaced apart from each other in the first direction (or Y-axis direction).

The (2-1)th metal pattern ML21 may be disposed to overlap at least a portion of the first active layer ACT1, and the (2-2)th metal pattern ML22 may be disposed to overlap at least a portion of the first active layer ACT1 and the second active layer ACT2. The (2-1)th metal pattern ML21 and the (2-2)th metal pattern ML22 may be patterned together with the second insulating layer 113. Each of the (2-1)th metal pattern ML21 and the (2-2)th metal pattern ML22 may not contact the active layer ACT1 and ACT2 with the second insulating layer interposed therebetween.

The (2-1)th metal pattern ML21 may serve as a mask in a conductive process of the active layer ACT1 and ACT2 such that a portion of the first active layer ACT1 overlapping the (2-1)th metal pattern ML21 is not conductive. The first active layer ACT1, which is not overlapped with the (2-1)th metal pattern ML21, may be configured as the conductive region ACT1_Co. The first active layer ACT1, which is overlapped with the (2-1)th metal pattern ML21, may be configured as the semiconductor channel of the driving transistor DR.

The (2-2)th metal pattern ML22 may serve as a mask in a conductive process of the active layer ACT1 and ACT2 such that a portion of the first active layer ACT1 and the second active layer ACT2 overlapping the (2-2)th metal pattern ML22 is not conductive. The first and second active layers ACT1 and ACT2, which are not overlapped with the (2-2)th metal pattern ML22, may be configured as the conductive region ACT1_Co and ACT2_Co. The first active layer ACT1 overlapped with the (2-2)th metal pattern ML22 may be configured as the semiconductor channel of the second switching transistor TR2. In addition, the second active layer ACT2 overlapped with the (2-2)th metal pattern ML22 may be configured as the semiconductor channel of the first switching transistor TR1.

The conductive process of the active layer ACT1 and ACT2 may use a plasma treatment to reduce the oxygen content of the oxide semiconductor of the active layer ACT1 and ACT2. For example, when the oxide semiconductor of the active layer ACT1 and ACT2 is exposed to plasma (conductive process), the oxygen contained in the oxide semiconductor may be removed, whereby a resistance of the oxide semiconductor is lowered, and thus the oxide semiconductor becomes conductive. For example, the plasma treatment may be a method of causing plasma discharge to helium He, hydrogen H2, or argon Ar gas. The exposed portion of the active layer ACT1 and ACT2, which is not overlapped with the (2-1)th metal pattern ML21 and the (2-2)th metal pattern ML22 of the second metal layer ML2, becomes conductive.

The planarization layer may be formed on the conductive active layer ACT1_Co and ACT2_Co and the second metal layer ML2. The planarization layer may be formed to cover the conductive active layer ACT1_Co and ACT2_Co and the second metal layer ML2. The fourth contact hole CH4 exposing at least a portion of the first active layer ACT1 may be formed in the planarization layer.

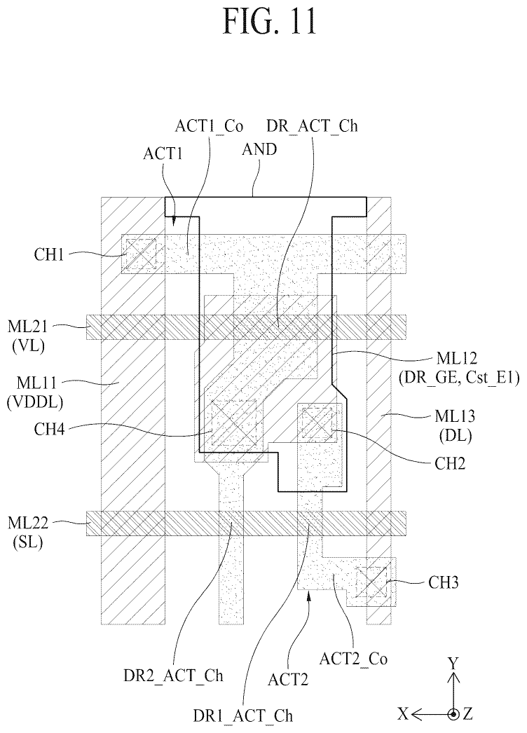

Referring to FIG. 11, the first electrode AND (or anode electrode) of the light emitting element ED may be formed on the planarization layer. The first electrode AND may extend from the light emitting area of each subpixel SP. The first electrode AND may be formed to overlap at least a portion of the first active layer ACT1 and the second active layer ACT2. The first electrode AND may be in contact with at least a portion of the first active layer ACT1 through the fourth contact hole CH4 formed in the planarization layer. In addition, the first electrode AND may be configured of the third electrode Cst_E3 of the storage capacitor Cst.

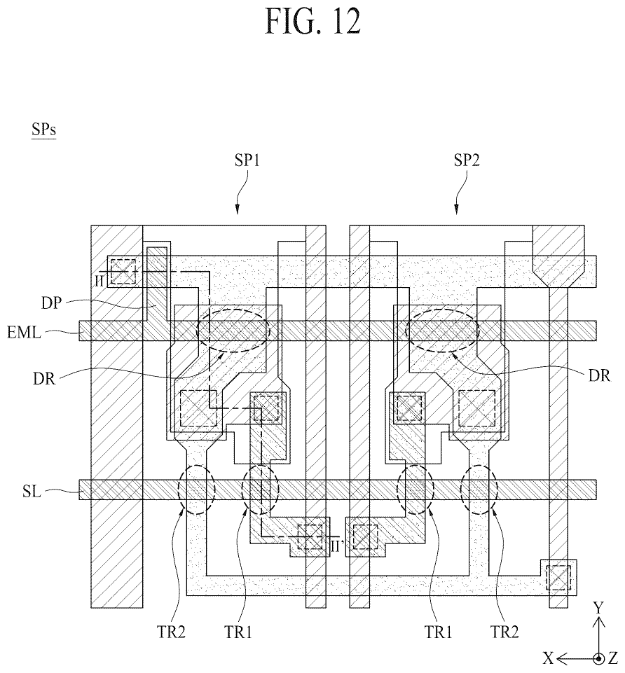

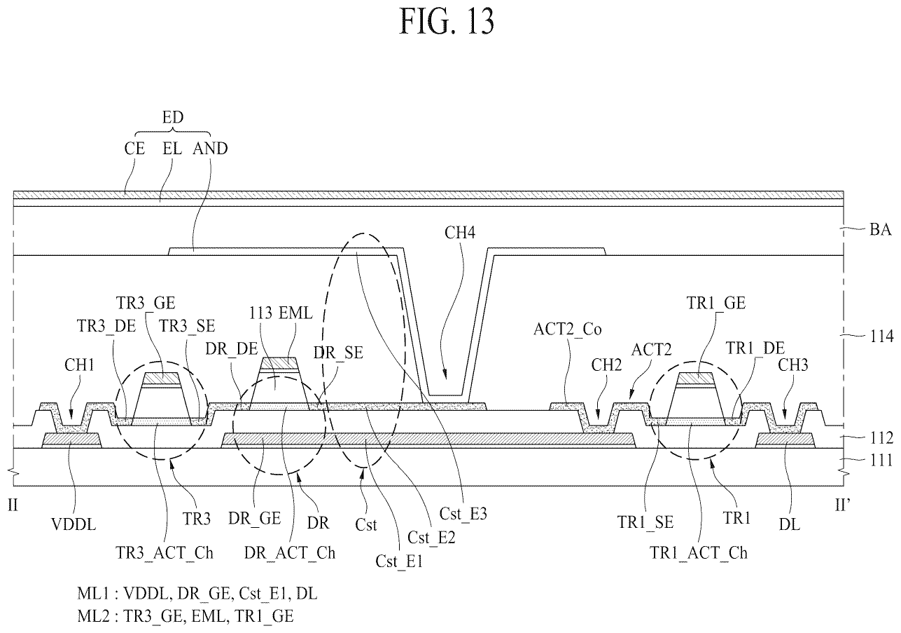

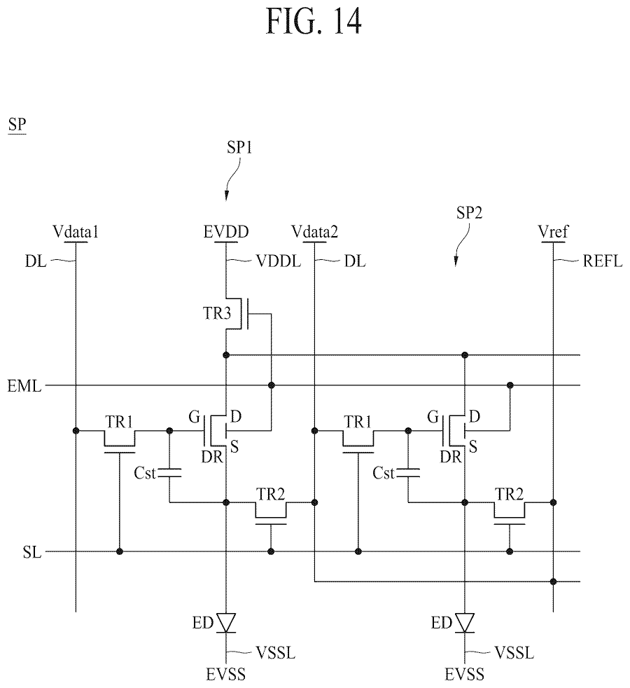

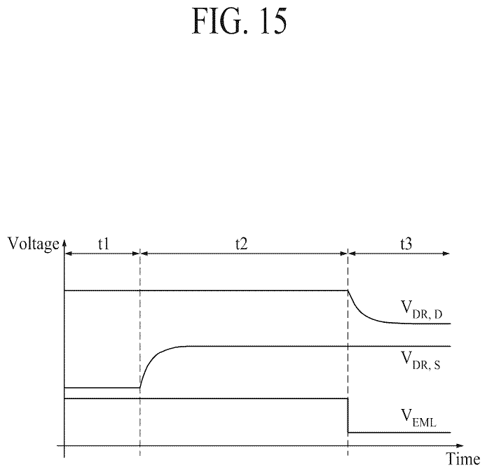

FIG. 12 is a plan view illustrating a subpixel of a light emitting display apparatus according to one or more embodiments of the present disclosure. FIG. 13 is a cross-sectional view along line II-II′ of FIG. 12 according to one or more embodiments of the present disclosure. FIG. 14 is a circuit diagram of a subpixel shown in FIG. 12 according to one or more embodiments of the present disclosure. FIG. 15 illustrates a node voltage of a driving transistor in the subpixel shown in FIG. 12 according to one or more embodiments of the present disclosure. FIGS. 12 to 15 are obtained by changing the configuration of the second metal layer in the display panel 110 described with reference to FIGS. 1 to 11. In the following description, the same reference numerals are assigned to the same elements except for the modified configuration, and repeated descriptions thereof will be omitted or briefly described.

Referring to FIGS. 12 to 15, each of a plurality of subpixels SP1 and SP2 according to another embodiment of the present disclosure may include a pixel circuit including at least one thin film transistor DR, TR1, and TR2 and a storage capacitor Cst. The plurality of subpixels SP1 and SP2 may include at least one signal line, and the at least one signal line may include a scan line SL (or first gate line) and an emission control line EML (or second gate line) extending in a second direction (or X-axis direction).

Referring to FIG. 12, a display panel 110 according to another embodiment of the present disclosure may further include a protruding pattern DP provided in at least one of the plurality of subpixels SP1 and SP2 and may further include a third switching transistor TR3 composed of the protruding pattern DP.

The plurality of subpixels SP1 and SP2 may be formed as a conductive line obtained by extending a portion of a conductive region ACT_Co of an active layer ACT connected to a first power line VDDL in the second direction (or X-axis direction). For example, the conductive line composed of the conductive region ACT_Co may be commonly connected to a driving transistor DR of each of the plurality of subpixels SP1 and SP2.

Referring to FIG. 13, a second metal layer ML2 according to another embodiment of the present disclosure may include a scan line SL (or first gate line), an emission control line EML (or second gate line), a protruding pattern DP, a gate electrode TR1_GE of a first switching transistor TR1, a gate electrode of a second switching transistor TR2, and a gate electrode TR3_GE of a third switching transistor TR3. In FIG. 13, the gate electrode of the second switching transistor TR2 is omitted.

The second metal layer ML2 is not in contact with the active layer ACT and first metal layer ML1 so that the second metal layer ML2 may serve as a mask pattern of a conductive process of the active layer ACT of the at least one thin film transistor DR, TR1, TR2, and TR3, and the second metal layer ML2 may be composed of the gate electrode TR1_GE of the first switching transistor TR1, the gate electrode (not shown) of the second switching transistor TR2, and the gate electrode TR3_GE of the third switching transistor TR3. For example, the gate electrode TR3_GE of the third switching transistor TR3 may be the protruding pattern DP protruding from the emission control line EML.

The scan line SL and the emission control line EML composed of the second metal layer ML2 may extend in the second direction (or X-axis direction). The scan line SL and the emission control line EML may be parallel to each other in the second direction (or X-axis direction) and may be spaced apart from each other in the first direction (or Y-axis direction).

The scan line SL may be applied with a scan signal Scan for controlling the first and second switching transistors TR1 and TR2 and may be composed of the gate electrode TR1_GE of each of the first and second switching transistors TR1 and TR2. For example, the scan signal Scan may be applied to the gate electrode TR1_GE of the first switching transistors TR1 and the gate electrode of the second switching transistor TR2 in order to control the first and second switching transistors TR1 and TR2.

The emission control signal (or emission signal) for controlling the third switching transistor TR3 may be applied to the emission control line EML. The protruding pattern DP of the emission control line EML may be configured as a gate electrode TR3_GE of the third switching transistor TR3.

Referring to FIGS. 14 and 15, in the display panel 110 according to one or more embodiments of the present disclosure, the protruding pattern DP protruding from the emission control line EML of the second metal layer ML2 may be composed of the third switching transistor TR3. For example, the third switching transistor TR3 may be disposed between the first power line VDDL and the driving transistor DT.

The third switching transistor TR3 may be turned-on in response to the emission control signal applied through an emission control line EML. When the third switching transistor TR3 is turned-on, a first power source voltage EVDD applied through the first power line VDDL may be transferred to a drain node D of the driving transistor DR. For example, the third switching transistor TR3 may be disposed in the first subpixel SP1 of the plurality of subpixels SP1 and SP2. When the third switching transistor TR3 is turned-on, the first power source voltage EVDD applied through the first power line VDDL may be commonly transferred to the drain node D of the driving transistor DR of each of the plurality of subpixels SP1 and SP2.

The emission control signal may be applied to the emission control line EML from a scan driver 120. A voltage V_{EML} of the emission control signal may be a gate-on voltage during first and second periods t1 and t2 in first to third periods t1, t2, and t3 in which the subpixel SP is operated, and may be a gate-off voltage during the third period t3. For example, the first period t1 may be an initialization period and a data program period before the subpixel SP emits light, the second period t2 may be a light emission period in which the subpixel SP emits light, and the third period t3 may be a period during which emission of the subpixel SP is stopped in the emission period.

A light emitting display apparatus according to one or more embodiments of the present disclosure will be described below.

A light emitting display apparatus according to one or more embodiments of the present disclosure may include a substrate, a first metal layer on the substrate, a first insulating layer on the first metal layer, a semiconductor layer on the first insulating layer, a second insulating layer on the semiconductor layer, and a second metal layer on the second insulating layer, at least one thin film transistor may comprise the semiconductor layer which is in contact with the first metal layer and is not in contact with the second metal layer.

According to one or more embodiments of the present disclosure, the second metal layer may not be in contact with the semiconductor layer and the first metal layer.

According to one or more embodiments of the present disclosure, the semiconductor layer may include an oxide semiconductor.

According to one or more embodiments of the present disclosure, at least one of the first metal layer and the second metal layer may include a low reflective material layer.

According to one or more embodiments of the present disclosure, the semiconductor layer may be connected to the first metal layer through at least one contact hole passing through the first insulating layer.

According to one or more embodiments of the present disclosure, the semiconductor layer may include a first semiconductor region and a second semiconductor region, the first semiconductor region overlapping with the second metal layer, and the second semiconductor region non-overlapping with the second metal layer.

According to one or more embodiments of the present disclosure, the first semiconductor region may overlap the second metal layer with the second insulating layer, the second insulating layer interposed between the first semiconductor region and second metal layer.

According to one or more embodiments of the present disclosure, the first semiconductor region may include a channel region of the at least one thin film transistor.

According to one or more embodiments of the present disclosure, the second semiconductor region may be exposed from the second insulating layer and the second metal layer.

According to one or more embodiments of the present disclosure, the second semiconductor region may include a conductive region.

According to one or more embodiments of the present disclosure, the second semiconductor region may include a source/drain electrode of the at least one thin film transistor.

According to one or more embodiments of the present disclosure, the at least one thin film transistor may include a driving transistor including the semiconductor layer and the first metal layer, and a first switching transistor and a second switching transistor, each of first switching transistor and the second switching transistor including the semiconductor layer and the second metal layer.

According to one or more embodiments of the present disclosure, a source/drain electrode of each of the driving transistor, the first switching transistor, and the second switching transistor may include a conductive region of the semiconductor layer.

According to one or more embodiments of the present disclosure, a gate electrode of the driving transistor may include the first metal layer, and a gate electrode of each of the first switching transistor and the second switching transistor may include the second metal layer.

According to one or more embodiments of the present disclosure, the gate electrode of the driving transistor may overlap with the second metal layer, and the gate electrode of each of the first switching transistor and the second switching transistor may be non-overlapping with the first metal layer.

According to one or more embodiments of the present disclosure, the second metal layer that overlaps with the gate electrode of the driving transistor may be electrically floated.

According to one or more embodiments of the present disclosure, the second metal layer that overlaps with the gate electrode of the driving transistor may have a voltage level lower than that of a source voltage of the driving transistor.

According to one or more embodiments of the present disclosure, the light emitting display apparatus may further include a light emitting element electrically connected to the driving transistor, and a storage capacitor including the first metal layer, the semiconductor layer, and a pixel electrode of the light emitting element.

According to one or more embodiments of the present disclosure, the light emitting display apparatus may further include a planarization layer covering the first insulating layer, the semiconductor layer, the second insulating layer, and the second metal layer, the light emitting element may be on the planarization layer, and the pixel electrode of the light emitting element may be connected to the semiconductor layer of the driving transistor through a contact hole passing through the planarization layer.

According to one or more embodiments of the present disclosure, the pixel electrode of the light emitting element may be connected to the conductive region constituting the source electrode of the driving transistor and a second electrode of the storage capacitor through a contact hole passing through the planarization layer.

According to one or more embodiments of the present disclosure, the first metal layer may include at least one power line and at least one signal line, the at least one power line and the at least one signal line extending in a first direction on the substrate, and the second metal layer may include a first gate line and a second gate line, the first gate line and the second gate line extending in a second direction crossing the first direction on the substrate.

According to one or more embodiments of the present disclosure, the first gate line and the second gate line may be parallel to each other in the second direction, and the first gate line and the second gate line may be spaced apart from each other in the first direction.

According to one or more embodiments of the present disclosure, the first gate line may be applied with a scan signal that controls the first switching transistor and the second switching transistor, and the first gate line may include a gate electrode of each of the first switching transistor and the second switching transistor.

According to one or more embodiments of the present disclosure, a driving voltage may be applied to the at least one power line, and a voltage different from the driving voltage may be applied to the second gate line.

According to one or more embodiments of the present disclosure, the second gate line may be applied with a voltage lower than the driving voltage applied to the at least one power line.

According to one or more embodiments of the present disclosure, the second gate line may be electrically floated.

According to one or more embodiments of the present disclosure, the second gate line may further include a protruding pattern protruding in the first direction, and the at least one thin film transistor may further include a third switching transistor, the third switching transistor comprises the semiconductor layer and the protruding pattern.

According to one or more embodiments of the present disclosure, the second gate line may be applied with an emission signal that controls the third switching transistor, and the protruding pattern of the second gate line may include a gate electrode of the third switching transistor.

According to one or more embodiments of the present disclosure, a voltage of the emission signal may be a gate-on voltage during first and second periods, and may be a gate-off voltage during a third period, and the first period may be an initialization period and a data program period before the subpixel emits light, the second period may be a light emission period in which the subpixel emits light, and the third period may be a period during which emission of the subpixel is stopped in the emission period.

According to one or more embodiments of the present disclosure, the substrate may include a plurality of subpixels, the plurality of subpixels including the light emitting element, the driving transistor, the storage capacitor, the first switching transistor, and the second switching transistor, and the third switching transistor may be in at least one of the plurality of subpixels arranged in the second direction.

A light emitting display apparatus according to one or more embodiments of the present disclosure may include a substrate including a plurality of subpixels, a first metal layer on the substrate, a first insulating layer on the first metal layer, a semiconductor layer on the first insulating layer, a planarization layer covering the first insulating layer and the semiconductor layer, and a light emitting element on the planarization layer, the semiconductor layer may be connected to the first metal layer through at least one contact hole passing through the first insulating layer, and the plurality of subpixels may include a driving transistor, and a pixel electrode of the light emitting element may be connected to the semiconductor layer of the driving transistor through a contact hole passing through the planarization layer.

It will be apparent to those skilled in the art that various modifications and variations may be made in the apparatus of the present disclosure without departing from the scope of the disclosure. Thus, it is intended that the present disclosure cover the modifications and variations of this disclosure provided that within the scope of the claims and their equivalents.

What is claimed is:

1. A light emitting display apparatus, comprising:
a substrate;
a first metal layer on the substrate;
a first insulating layer on the first metal layer;
a semiconductor layer on the first insulating layer;
a second insulating layer on the semiconductor layer; and
a second metal layer on the second insulating layer,
wherein at least one thin film transistor comprises the semiconductor layer which is in contact with the first metal layer and is not in contact with the second metal layer.

2. The light emitting display apparatus according to claim 1, wherein the second metal layer is not in contact with the semiconductor layer and the first metal layer.

3. The light emitting display apparatus according to claim 1, wherein the semiconductor layer includes an oxide semiconductor.

4. The light emitting display apparatus according to claim 1, wherein at least one of the first metal layer and the second metal layer includes a low reflective material layer.

5. The light emitting display apparatus according to claim 1, wherein the semiconductor layer is connected to the first metal layer through at least one contact hole passing through the first insulating layer.

6. The light emitting display apparatus according to claim 1, wherein the semiconductor layer includes a first semiconductor region and a second semiconductor region, the first semiconductor region overlapping with the second metal layer, and the second semiconductor region non-overlapping with the second metal layer.

7. The light emitting display apparatus according to claim 6, wherein the first semiconductor region overlaps the second metal layer with the second insulating layer, the second insulating layer interposed between the first semiconductor region and second metal layer.

8. The light emitting display apparatus according to claim 6, wherein the first semiconductor region includes a channel region of the at least one thin film transistor.

9. The light emitting display apparatus according to claim 6, wherein the second semiconductor region is exposed from the second insulating layer and the second metal layer.

10. The light emitting display apparatus according to claim 6, wherein the second semiconductor region includes a conductive region.

11. The light emitting display apparatus according to claim 6, wherein the second semiconductor region includes a source/drain electrode of the at least one thin film transistor.

12. The light emitting display apparatus according to claim 1, wherein the at least one thin film transistor includes:
a driving transistor including the semiconductor layer and the first metal layer; and
a first switching transistor and a second switching transistor, each of first switching transistor and the second switching transistor including the semiconductor layer and the second metal layer.

13. The light emitting display apparatus according to claim 12, wherein a source/drain electrode of each of the driving transistor, the first switching transistor, and the second switching transistor includes a conductive region of the semiconductor layer.

14. The light emitting display apparatus according to claim 12,
wherein a gate electrode of the driving transistor includes the first metal layer, and
wherein a gate electrode of each of the first switching transistor and the second switching transistor includes the second metal layer.

15. The light emitting display apparatus according to claim 14, wherein the gate electrode of the driving transistor overlaps with the second metal layer, and
wherein the gate electrode of each of the first switching transistor and the second switching transistor is non-overlapping with the first metal layer.

16. The light emitting display apparatus according to claim 15, wherein the second metal layer that overlaps with the gate electrode of the driving transistor is electrically floated.

17. The light emitting display apparatus according to claim 15, wherein the second metal layer that overlaps with the gate electrode of the driving transistor has a voltage level lower than that of a source voltage of the driving transistor.

18. The light emitting display apparatus according to claim 12, further comprising:
a light emitting element electrically connected to the driving transistor; and
a storage capacitor including the first metal layer, the semiconductor layer, and a pixel electrode of the light emitting element.

19. The light emitting display apparatus according to claim 18, further comprising:
a planarization layer covering the first insulating layer, the semiconductor layer, the second insulating layer, and the second metal layer,
wherein the light emitting element is on the planarization layer, and
wherein the pixel electrode of the light emitting element is connected to the semiconductor layer of the driving transistor through a contact hole passing through the planarization layer.

20. The light emitting display apparatus according to claim 19, wherein the pixel electrode of the light emitting element is connected to the conductive region constituting the source electrode of the driving transistor and a second electrode of the storage capacitor through a contact hole passing through the planarization layer.

21. The light emitting display apparatus according to claim 19, wherein the first metal layer includes at least one power line and at least one signal line, the at least one power line and the at least one signal line extending in a first direction on the substrate, and
wherein the second metal layer includes a first gate line and a second gate line, the first gate line and the second gate line extending in a second direction crossing the first direction on the substrate.

22. The light emitting display apparatus according to claim 21, wherein the first gate line and the second gate line are parallel to each other in the second direction, and the first gate line and the second gate line are spaced apart from each other in the first direction.

23. The light emitting display apparatus according to claim 22, wherein the first gate line is applied with a scan signal that controls the first switching transistor and the second switching transistor, and the first gate line includes a gate electrode of each of the first switching transistor and the second switching transistor.

24. The light emitting display apparatus according to claim 22, wherein a driving voltage is applied to the at least one power line, and a voltage different from the driving voltage is applied to the second gate line.

25. The light emitting display apparatus according to claim 24, wherein the second gate line is applied with a voltage lower than the driving voltage applied to the at least one power line.

26. The light emitting display apparatus according to claim 22, wherein the second gate line is electrically floated.

27. The light emitting display apparatus according to claim 22, wherein the second gate line further includes a protruding pattern protruding in the first direction, and
wherein the at least one thin film transistor further includes a third switching transistor, the third switching transistor comprises the semiconductor layer and the protruding pattern.

28. The light emitting display apparatus according to claim 27, wherein the second gate line is applied with an emission signal that controls the third switching transistor, and
wherein the protruding pattern of the second gate line includes a gate electrode of the third switching transistor.

29. The light emitting display apparatus according to claim 28, wherein a voltage of the emission signal is a gate-on voltage during first and second periods, and is a gate-off voltage during a third period, and
wherein the first period is an initialization period and a data program period before the subpixel emits light, the second period is a light emission period in which the subpixel emits light, and the third period is a period during which emission of the subpixel is stopped in the emission period.

30. The light emitting display apparatus according to claim 27, wherein the substrate includes a plurality of subpixels, the plurality of subpixels including the light emitting element, the driving transistor, the storage capacitor, the first switching transistor, and the second switching transistor, and
wherein the third switching transistor is in at least one of the plurality of subpixels arranged in the second direction.

31. A light emitting display apparatus comprising:
a substrate including a plurality of subpixels;
a first metal layer on the substrate;
a first insulating layer on the first metal layer;
a semiconductor layer on the first insulating layer;
a planarization layer covering the first insulating layer and the semiconductor layer; and
a light emitting element on the planarization layer,
wherein the semiconductor layer is connected to the first metal layer through at least one contact hole passing through the first insulating layer, and
wherein the plurality of subpixels include a driving transistor, and a pixel electrode of the light emitting element is connected to the semiconductor layer of the driving transistor through a contact hole passing through the planarization layer.
